(19) United States
(12) Patent Application Publication
(10) Pub. No.: US 2025/0315684 A1
(43) Pub. Date: Oct. 9, 2025

(54) SYSTEM AND METHOD FOR IMPLEMENTING A MODEL THAT PREDICTS THE PROBABILITY OF HALLUCINATION FOR ANY QUERY IMPOSED TO AN LLM

(71) Applicant: JPMorgan Chase Bank, N.A., New York, NY (US)

(72) Inventors: William WATSON, Long Beach, NY (US); Naan CHO, New York, NY (US); Manuela VELOSO, New York, NY (US)

(73) Assignee: JPMorgan Chase Bank, N.A., New York, NY (US)

(21) Appl. No.: 18/630,641

(22) Filed: Apr. 9, 2024

(51) Int. Cl. G06N 3/09; G06F 30/27

(52) U.S. Cl. CPC G06N 3/09; G06F 30/27

(57) ABSTRACT

Various methods and processes, apparatuses or systems, and media for predicting probability of hallucination before generation for a query imposed to a Large Language Model (LLM) are disclosed. A processor causes a trained generative model to receive a query from a user via a user interface operatively connected to the generative model; perturbs the received query n times into unique variations that retain the original semantic meaning of the received query yet significantly diverge lexically; implements n+1 independent agents to sample an output from each query including the original received query; applies the simulation algorithm on the sampled outputs; derives an empirical estimate into an expected rate of hallucination for the original received query as a ground truth for the encoder; and outputs a probability of hallucination value for the query received by the generative model before the LLM generates an output.

### TECHNICAL FIELD

This disclosure generally relates to data processing, and, more particularly, to methods and apparatuses for implementing a platform, language, cloud, and database agnostic probability of hallucination predicting module configured to implement a model that predicts the probability of hallucination before generation, for any query imposed to a Large Language Model (LLM).

### BACKGROUND

The developments described in this section are known to the inventors. However, unless otherwise indicated, it should not be assumed that any of the developments described in this section qualify as prior art merely by virtue of their inclusion in this section, or that these developments are known to a person of ordinary skill in the art.

Hallucination continues to be one of the most critical challenges in the institutional adoption journey of LLMs. In general terms, hallucination refers to a false perception of patterns or objects resulting from one's senses. With regards to LLMs, a myriad of studies have categorized hallucinations into bifurcated structures such as (1) intrinsic hallucination, which refers to the LLM's outputs directly contradicting with the source content for extractive queries, or (2) extrinsic hallucination, which refers to the LLM's outputs being unverifiable by the source content (i.e. irrelevant outputs). From a different angle, (1) factuality hallucinations refer to outputs which directly contradict or fabricate the ground truth while (2) faithfulness hallucinations define outputs that misunderstand the context or intent of the query.

Despite the promising potential for a myriad of practical use cases, LLMs appear to offer limited insights into their chain of thought and may have the propensity to hallucinate in various circumstances. Common factors that drive hallucinations may encompass high model complexity, flawed data sources, or inherent sampling randomness.

Specifically, the intrinsic trade-off between greedy deterministic decoding and the creativity spawned through nucleus sampling may induce a heightened propensity to generate hallucinations. This challenge may be compounded by limitations such as the frequent inaccessibility into the LLMs' training datasets. Several studies have highlighted the importance of resolving hallucination-related issues via the concerted effort of evaluating different LLMs. In this context, the majority of current studies have focused on the post generation phase of output analysis, such as, self-refinement via feedback loops on the model's output, analysis of logit output values to detect hallucination, or for a minority of studies focused on the pre-generation phase, the ingestion of recent knowledge to improve performance.

For example, according to conventional techniques of confidence estimation, a user may input a query to generate an output that is accurate or hallucinatory. If hallucinatory, the user may end the session or revise the query for iterative rounds of generation. However, conventional techniques fail to propose any possible solution in predicting the probability of hallucination, before any generation, for any type of query.

### SUMMARY

The present disclosure, through one or more of its various aspects, embodiments, and/or specific features or sub-components, provides, among other features, various systems, servers, devices, methods, media, programs, and platforms for implementing a platform, language, cloud, and database agnostic probability of hallucination predicting module configured to implement a model that predicts the probability of hallucination before generation, for any query imposed to an LLM, but the disclosure is not limited thereto. Therefore, users can instantly gain insight into hallucination probability and revise a query accordingly.

For example, the model implemented by the probability of hallucination predicting module may predict both binary and multi-class probabilities of hallucination, enabling a means to judge the query's quality with regards to its propensity to hallucinate. Therefore, the model paves the way to revise or cancel a query before generation and the ensuing computational waste. Moreover, it may provide a lucid means to measure user accountability for hallucinatory queries.

According to exemplary embodiments, a method for predicting probability of hallucination before generation for a query imposed to an LLM by utilizing one or more processors along with allocated memory is disclosed. The method may include: implementing a generative model; training the generative model via a method of leveraging a simulation algorithm for construction of an encoder for hallucination; receiving a query by the generative model from a user via a user interface operatively connected to the generative model; perturbing the received query n times into unique variations that retain the original semantic meaning of the received query yet diverge lexically; implementing n+1 independent agents to sample an output from each query including the original received query; applying the simulation algorithm on the sampled outputs; deriving an empirical estimate into an expected rate of hallucination for the original received query as a ground truth for the encoder; and outputting a probability of hallucination value for the query received by the generative model before the LLM generates an output in response to the received query.

According to exemplary embodiments, the term “encoder” as disclosed herein is not limited to an encoder only. The term “encoder” may broadly encompass one or more of the following: encoder, auto-encoding encoder, decoder, autoregressive decoder, sequence model, e.g., Long Short-Term Memory (LSTM) network or Recurrent Neural Network (RNN) or Gated Recurrent Unit (GRU), but the disclosure is not limited thereto.

According to exemplary embodiments, in implementing the method, the simulation algorithm may be a Multi-Agent Monte Carlo Simulation algorithm, but the disclosure is not limited there, and the empirical estimate that is provided through the Multi-Agent Monte Carlo Simulation algorithm may be proportional to an approximation of hallucination rate.

According to exemplary embodiments, the method may further include: estimating, by the trained generative model, a binary classification of the received query's propensity to hallucinate before generation.

According to exemplary embodiments, the method may further include: estimating a multi-class hallucination rate estimating an expected value of hallucination via sampling before generation.

According to exemplary embodiments, the method may further include: training a binary model to estimate propensity the received query can hallucinate.

According to exemplary embodiments, the method may further include: training a multi-class model to predict expected value of hallucinations when sampled n+1 times.

According to exemplary embodiments, a system for predicting probability of hallucination before generation for a query imposed to an LLM is disclosed. The system may include: a processor; and a memory operatively connected to the processor via a communication interface, the memory storing computer readable instructions, when executed, may cause the processor to: implement a generative model; train the generative model via a method of leveraging a simulation algorithm for construction of an encoder for hallucination; receive a query by the generative model from a user via a user interface operatively connected to the generative model; perturb the received query n times into unique variations that retain the original semantic meaning of the received query yet diverge lexically; implement n+1 independent agents to sample an output from each query including the original received query; apply the simulation algorithm on the sampled outputs; derive an empirical estimate into an expected rate of hallucination for the original received query as a ground truth for the encoder; and output a probability of hallucination value for the query received by the generative model before the LLM generates an output in response to the received query.

According to exemplary embodiments, the processor may be further configured to implement the simulation algorithm which may be a Multi-Agent Monte Carlo Simulation algorithm, but the disclosure is not limited thereto. The empirical estimate that is provided through the Multi-Agent Monte Carlo Simulation algorithm implemented by the processor may be proportional to an approximation of hallucination rate.

According to exemplary embodiments, the processor may be further configured to: estimate, by the trained generative model, a binary classification of the received query's propensity to hallucinate before generation.

According to exemplary embodiments, the processor may be further configured to: estimate a multi-class hallucination rate estimating an expected value of hallucination via sampling before generation.

According to exemplary embodiments, the processor may be further configured to: train a binary model to estimate propensity the received query can hallucinate.

According to exemplary embodiments, the processor may be further configured to: train a multi-class model to predict expected value of hallucinations when sampled n+1 times.

According to exemplary embodiments, a non-transitory computer readable medium configured to store instructions for predicting probability of hallucination before generation for a query imposed to an LLM is disclosed. The instructions, when executed, may cause a processor to perform the following: implementing a generative model; training the generative model via a method of leveraging a simulation algorithm for construction of an encoder for hallucination; receiving a query by the generative model from a user via a user interface operatively connected to the generative model; perturbing the received query n times into unique variations that retain the original semantic meaning of the received query yet diverge lexically; implementing n+1 independent agents to sample an output from each query including the original received query; applying the simulation algorithm on the sampled outputs; deriving an empirical estimate into an expected rate of hallucination for the original received query as a ground truth for the encoder; and outputting a probability of hallucination value for the query received by the generative model before the LLM generates an output in response to the received query.

According to exemplary embodiments, in implementing the process by the processor, the simulation algorithm may be a Multi-Agent Monte Carlo Simulation algorithm, but the disclosure is not limited there, and the empirical estimate that is provided through the Multi-Agent Monte Carlo Simulation algorithm may be proportional to an approximation of hallucination rate.

According to exemplary embodiments, the instructions, when executed, may cause the processor to further perform the following: estimating, by the trained generative model, a binary classification of the received query's propensity to hallucinate before generation.

According to exemplary embodiments, the instructions, when executed, may cause the processor to further perform the following: estimating a multi-class hallucination rate estimating an expected value of hallucination via sampling before generation.

According to exemplary embodiments, the instructions, when executed, may cause the processor to further perform the following: training a binary model to estimate propensity the received query can hallucinate.

According to exemplary embodiments, the instructions, when executed, may cause the processor to further perform the following: training a multi-class model to predict expected value of hallucinations when sampled n+1 times.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a computer system for implementing a platform, language, database, and cloud agnostic probability of hallucination predicting module configured to implement a model that predicts the probability of hallucination before generation, for any query imposed to an LLM in accordance with an exemplary embodiment.

FIG. 2 illustrates an exemplary diagram of a network environment with a platform, language, database, and cloud agnostic probability of hallucination predicting device in accordance with an exemplary embodiment.

FIG. 3 illustrates a system diagram for implementing a platform, language, database, and cloud agnostic probability of hallucination predicting device having a platform, language, database, and cloud agnostic probability of hallucination predicting module in accordance with an exemplary embodiment.

FIG. 4 illustrates a system diagram for implementing a platform, language, database, and cloud agnostic probability of hallucination predicting module of FIG. 3 in accordance with an exemplary embodiment.

FIG. 5 illustrates an exemplary model training methodology implemented by the platform, language, database, and cloud agnostic probability of hallucination predicting module of FIG. 4 in accordance with an exemplary embodiment.

FIG. 6 illustrates an exemplary flow chart of a process implemented by the platform, language, database, and cloud agnostic probability of hallucination predicting module of FIG. 4 for implementing a model that predicts the probability of hallucination before generation, for any query imposed to an LLM in accordance with an exemplary embodiment.

### DETAILED DESCRIPTION

Through one or more of its various aspects, embodiments and/or specific features or sub-components of the present disclosure, are intended to bring out one or more of the advantages as specifically described above and noted below.

The examples may also be embodied as one or more non-transitory computer readable media having instructions stored thereon for one or more aspects of the present technology as described and illustrated by way of the examples herein. The instructions in some examples include executable code that, when executed by one or more processors, cause the processors to carry out steps necessary to implement the methods of the examples of this technology that are described and illustrated herein.

As is traditional in the field of the present disclosure, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the inventive concepts. Further, the blocks, units and/or modules of the example embodiments may be physically combined into more complex blocks, units and/or modules without departing from the scope of the present disclosure.

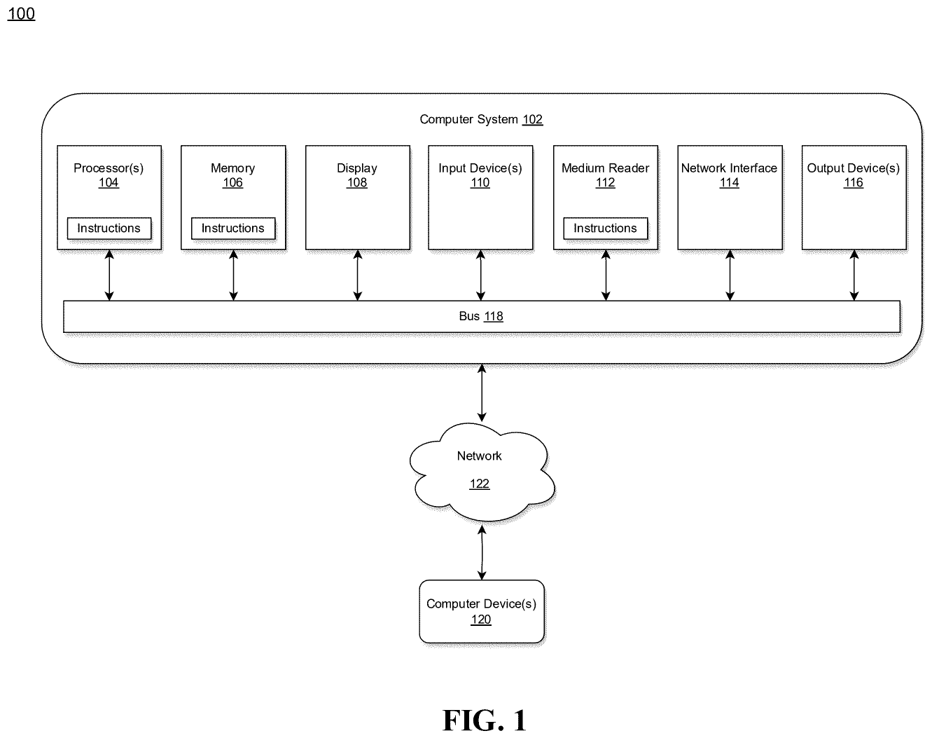

FIG. 1 is an exemplary system 100 for use in implementing a platform, language, database, and cloud agnostic probability of hallucination predicting module configured to implement a model that predicts the probability of hallucination before generation, for any query imposed to an LLM in accordance with an exemplary embodiment. The system 100 is generally shown and may include a computer system 102, which is generally indicated.

The computer system 102 may include a set of instructions that can be executed to cause the computer system 102 to perform any one or more of the methods or computer-based functions disclosed herein, either alone or in combination with the other described devices. The computer system 102 may operate as a standalone device or may be connected to other systems or peripheral devices. For example, the computer system 102 may include, or be included within, any one or more computers, servers, systems, communication networks or cloud environment. Even further, the instructions may be operative in such cloud-based computing environment.

In a networked deployment, the computer system 102 may operate in the capacity of a server or as a client user computer in a server-client user network environment, a client user computer in a cloud computing environment, or as a peer computer system in a peer-to-peer (or distributed) network environment. The computer system 102, or portions thereof, may be implemented as, or incorporated into, various devices, such as a personal computer, a tablet computer, a set-top box, a personal digital assistant, a mobile device, a palmtop computer, a laptop computer, a desktop computer, a communications device, a wireless smart phone, a personal trusted device, a wearable device, a global positioning satellite (GPS) device, a web appliance, or any other machine capable of executing a set of instructions (sequential or otherwise) that specify actions to be taken by that machine. Further, while a single computer system 102 is illustrated, additional embodiments may include any collection of systems or sub-systems that individually or jointly execute instructions or perform functions. The term system shall be taken throughout the present disclosure to include any collection of systems or sub-systems that individually or jointly execute a set, or multiple sets, of instructions to perform one or more computer functions.

As illustrated in FIG. 1, the computer system 102 may include at least one processor 104. The processor 104 is tangible and non-transitory. As used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The processor 104 is an article of manufacture and/or a machine component. The processor 104 is configured to execute software instructions in order to perform functions as described in the various embodiments herein. The processor 104 may be a general-purpose processor or may be part of an application specific integrated circuit (ASIC). The processor 104 may also be a microprocessor, a microcomputer, a processor chip, a controller, a microcontroller, a digital signal processor (DSP), a state machine, or a programmable logic device. The processor 104 may also be a logical circuit, including a programmable gate array (PGA) such as a field programmable gate array (FPGA), or another type of circuit that includes discrete gate and/or transistor logic. The processor 104 may be a central processing unit (CPU), a graphics processing unit (GPU), or both. Additionally, any processor described herein may include multiple processors, parallel processors, or both. Multiple processors may be included in, or coupled to, a single device or multiple devices.

The computer system 102 may also include a computer memory 106. The computer memory 106 may include a static memory, a dynamic memory, or both in communication. Memories described herein are tangible storage mediums that can store data and executable instructions, and are non-transitory during the time instructions are stored therein. Again, as used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The memories are an article of manufacture and/or machine component. Memories described herein are computer-readable mediums from which data and executable instructions can be read by a computer. Memories as described herein may be random access memory (RAM), read only memory (ROM), flash memory, electrically programmable read only memory (EPROM), electrically erasable programmable read-only memory (EEPROM), registers, a hard disk, a cache, a removable disk, tape, compact disk read only memory (CD-ROM), digital versatile disk (DVD), floppy disk, or any other form of storage medium known in the art. Memories may be volatile or non-volatile, secure and/or encrypted, unsecure and/or unencrypted. Of course, the computer memory 106 may comprise any combination of memories or a single storage.

The computer system 102 may further include a display 108, such as a liquid crystal display (LCD), an organic light emitting diode (OLED), a flat panel display, a solid-state display, a cathode ray tube (CRT), a plasma display, or any other known display.

The computer system 102 may also include at least one input device 110, such as a keyboard, a touch-sensitive input screen or pad, a speech input, a mouse, a remote control device having a wireless keypad, a microphone coupled to a speech recognition engine, a camera such as a video camera or still camera, a cursor control device, a GPS device, a visual positioning system (VPS) device, an altimeter, a gyroscope, an accelerometer, a proximity sensor, or any combination thereof. Those skilled in the art appreciate that various embodiments of the computer system 102 may include multiple input devices 110. Moreover, those skilled in the art further appreciate that the above-listed, exemplary input devices 110 are not meant to be exhaustive and that the computer system 102 may include any additional, or alternative, input devices 110.

The computer system 102 may also include a medium reader 112 which is configured to read any one or more sets of instructions, e.g., software, from any of the memories described herein. The instructions, when executed by a processor, can be used to perform one or more of the methods and processes as described herein. In a particular embodiment, the instructions may reside completely, or at least partially, within the memory 106, the medium reader 112, and/or the processor 104 during execution by the computer system 102.

Furthermore, the computer system 102 may include any additional devices, components, parts, peripherals, hardware, software, or any combination thereof which are commonly known and understood as being included with or within a computer system, such as, but not limited to, a network interface 114 and an output device 116. The output device 116 may be, but is not limited to, a speaker, an audio out, a video out, a remote control output, a printer, or any combination thereof.

Each of the components of the computer system 102 may be interconnected and communicate via a bus 118 or other communication link. As shown in FIG. 1, the components may each be interconnected and communicate via an internal bus. However, those skilled in the art appreciate that any of the components may also be connected via an expansion bus. Moreover, the bus 118 may enable communication via any standard or other specification commonly known and understood such as, but not limited to, peripheral component interconnect, peripheral component interconnect express, parallel advanced technology attachment, serial advanced technology attachment, etc.

The computer system 102 may be in communication with one or more additional computer devices 120 via a network 122. The network 122 may be, but is not limited to, a local area network, a wide area network, the Internet, a telephony network, a short-range network, or any other network commonly known and understood in the art. The short-range network may include, for example, infrared, near field communication, ultraband, or any combination thereof. Those skilled in the art appreciate that additional networks 122 which are known and understood may additionally or alternatively be used and that the exemplary networks 122 are not limiting or exhaustive. Also, while the network 122 is shown in FIG. 1 as a wireless network, those skilled in the art appreciate that the network 122 may also be a wired network.

The additional computer device 120 is shown in FIG. 1 as a personal computer. However, those skilled in the art appreciate that, in alternative embodiments of the present application, the computer device 120 may be a laptop computer, a tablet PC, a personal digital assistant, a mobile device, a palmtop computer, a desktop computer, a communications device, a wireless telephone, a personal trusted device, a web appliance, a server, or any other device that is capable of executing a set of instructions, sequential or otherwise, that specify actions to be taken by that device. Of course, those skilled in the art appreciate that the above-listed devices are merely exemplary devices and that the device 120 may be any additional device or apparatus commonly known and understood in the art without departing from the scope of the present application. For example, the computer device 120 may be the same or similar to the computer system 102. Furthermore, those skilled in the art similarly understand that the device may be any combination of devices and apparatuses.

Of course, those skilled in the art appreciate that the above-listed components of the computer system 102 are merely meant to be exemplary and are not intended to be exhaustive and/or inclusive. Furthermore, the examples of the components listed above are also meant to be exemplary and similarly are not meant to be exhaustive and/or inclusive.

According to exemplary embodiments, the probability of hallucination predicting module implemented by the system 100 may be platform, language, database, and cloud agnostic that may allow for consistent easy orchestration and passing of data through various components to output a desired result regardless of platform, browser, language, database, and cloud environment by writing programs accordingly. Since the disclosed process, according to exemplary embodiments, is platform, language, database, browser, and cloud agnostic, the probability of hallucination predicting module may be independently tuned or modified for optimal performance without affecting the configuration or data files. The configuration or data files, according to exemplary embodiments, may be written using JSON, but the disclosure is not limited thereto. For example, the configuration or data files may easily be extended to other readable file formats such as XML, YAML, etc., or any other configuration based languages.

In accordance with various embodiments of the present disclosure, the methods described herein may be implemented using a hardware computer system that executes software programs. Further, in an exemplary, non-limited embodiment, implementations can include distributed processing, component/object distributed processing, and an operation mode having parallel processing capabilities. Virtual computer system processing can be constructed to implement one or more of the methods or functionality as described herein, and a processor described herein may be used to support a virtual processing environment.

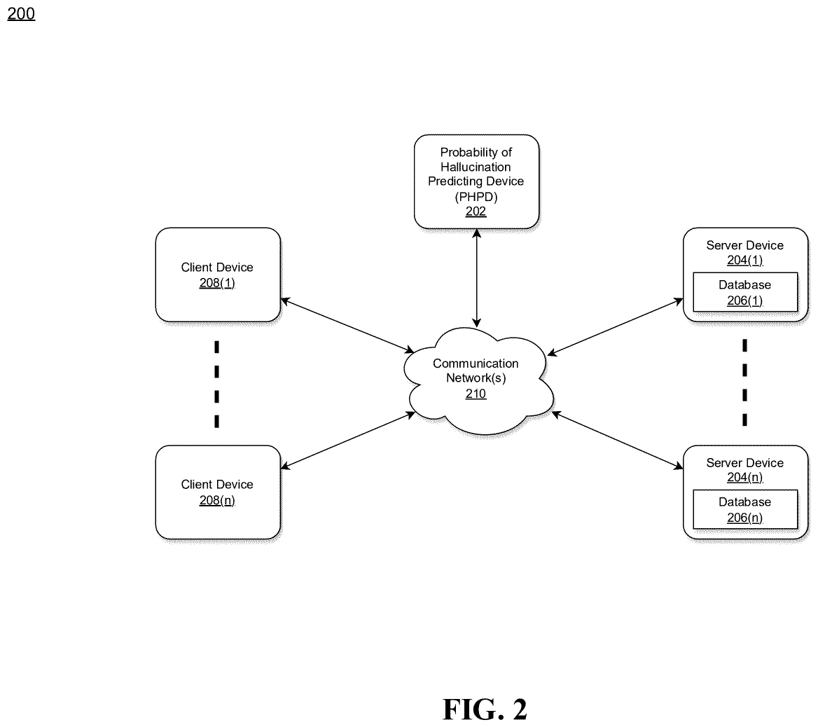

Referring to FIG. 2, a schematic of an exemplary network environment 200 for implementing a language, platform, database, and cloud agnostic probability of hallucination predicting device (PHPD) of the instant disclosure is illustrated.

According to exemplary embodiments, the above-described problems associated with conventional tools may be overcome by implementing an PHPD 202 as illustrated in FIG. 2 that may be configured for implementing a platform, language, database, and cloud agnostic probability of hallucination predicting module configured to implement a model that predicts the probability of hallucination before generation, for any query imposed to an LLM, but the disclosure is not limited thereto. Therefore, users can instantly gain insight into hallucination probability and revise a query accordingly. For example, the model implemented by the PHPD may predict both binary and multi-class probabilities of hallucination, enabling a means to judge the query's quality with regards to its propensity to hallucinate. Therefore, the model paves the way to revise or cancel a query before generation and the ensuing computational waste. Moreover, it may provide a lucid means to measure user accountability for hallucinatory queries.

The PHPD 202 may have one or more computer system 102s, as described with respect to FIG. 1, which in aggregate provide the necessary functions.

The PHPD 202 may store one or more applications that can include executable instructions that, when executed by the PHPD 202, cause the PHPD 202 to perform actions, such as to transmit, receive, or otherwise process network messages, for example, and to perform other actions described and illustrated below with reference to the figures. The application(s) may be implemented as modules or components of other applications. Further, the application(s) can be implemented as operating system extensions, modules, plugins, or the like.

Even further, the application(s) may be operative in a cloud-based computing environment. The application(s) may be executed within or as virtual machine(s) or virtual server(s) that may be managed in a cloud-based computing environment. Also, the application(s), and even the PHPD 202 itself, may be located in virtual server(s) running in a cloud-based computing environment rather than being tied to one or more specific physical network computing devices. Also, the application(s) may be running in one or more virtual machines (VMs) executing on the PHPD 202. Additionally, in one or more embodiments of this technology, virtual machine(s) running on the PHPD 202 may be managed or supervised by a hypervisor.

In the network environment 200 of FIG. 2, the PHPD 202 is coupled to a plurality of server devices 204(1)-204(n) that hosts a plurality of databases 206(1)-206(n), and also to a plurality of client devices 208(1)-208(n) via communication network(s) 210. A communication interface of the PHPD 202, such as the network interface 114 of the computer system 102 of FIG. 1, operatively couples and communicates between the PHPD 202, the server devices 204(1)-204(n), and/or the client devices 208(1)-208(n), which are all coupled together by the communication network(s) 210, although other types and/or numbers of communication networks or systems with other types and/or numbers of connections and/or configurations to other devices and/or elements may also be used.

The communication network(s) 210 may be the same or similar to the network 122 as described with respect to FIG. 1, although the PHPD 202, the server devices 204(1)-204(n), and/or the client devices 208(1)-208(n) may be coupled together via other topologies. Additionally, the network environment 200 may include other network devices such as one or more routers and/or switches, for example, which are well known in the art and thus will not be described herein.

By way of example only, the communication network(s) 210 may include local area network(s) (LAN(s)) or wide area network(s) (WAN(s)), and can use TCP/IP over Ethernet and industry-standard protocols, although other types and/or numbers of protocols and/or communication networks may be used. The communication network(s) 210 in this example may employ any suitable interface mechanisms and network communication technologies including, for example, teletraffic in any suitable form (e.g., voice, modem, and the like), Public Switched Telephone Network (PSTNs), Ethernet-based Packet Data Networks (PDNs), combinations thereof, and the like.

The PHPD 202 may be a standalone device or integrated with one or more other devices or apparatuses, such as one or more of the server devices 204(1)-204(n), for example. In one particular example, the PHPD 202 may be hosted by one of the server devices 204(1)-204(n), and other arrangements are also possible. Moreover, one or more of the devices of the PHPD 202 may be in the same or a different communication network including one or more public, private, or cloud networks, for example.

The plurality of server devices 204(1)-204(n) may be the same or similar to the computer system 102 or the computer device 120 as described with respect to FIG. 1, including any features or combination of features described with respect thereto. For example, any of the server devices 204(1)-204(n) may include, among other features, one or more processors, a memory, and a communication interface, which are coupled together by a bus or other communication link, although other numbers and/or types of network devices may be used. The server devices 204(1)-204(n) in this example may process requests received from the PHPD 202 via the communication network(s) 210 according to the HTTP-based and/or JavaScript Object Notation (JSON) protocol, for example, although other protocols may also be used.

The server devices 204(1)-204(n) may be hardware or software or may represent a system with multiple servers in a pool, which may include internal or external networks. The server devices 204(1)-204(n) hosts the databases 206(1)-206(n) that are configured to store metadata sets, data quality rules, and newly generated data.

Although the server devices 204(1)-204(n) are illustrated as single devices, one or more actions of each of the server devices 204(1)-204(n) may be distributed across one or more distinct network computing devices that together comprise one or more of the server devices 204(1)-204(n). Moreover, the server devices 204(1)-204(n) are not limited to a particular configuration. Thus, the server devices 204(1)-204(n) may contain a plurality of network computing devices that operate using a master/slave approach, whereby one of the network computing devices of the server devices 204(1)-204(n) operates to manage and/or otherwise coordinate operations of the other network computing devices.

The server devices 204(1)-204(n) may operate as a plurality of network computing devices within a cluster architecture, a peer-to peer architecture, virtual machines, or within a cloud architecture, for example. Thus, the technology disclosed herein is not to be construed as being limited to a single environment and other configurations and architectures are also envisaged.

The plurality of client devices 208(1)-208(n) may also be the same or similar to the computer system 102 or the computer device 120 as described with respect to FIG. 1, including any features or combination of features described with respect thereto. Client device in this context refers to any computing device that interfaces to communications network(s) 210 to obtain resources from one or more server devices 204(1)-204(n) or other client devices 208(1)-208(n).

According to exemplary embodiments, the client devices 208(1)-208(n) in this example may include any type of computing device that can facilitate the implementation of the PHPD 202 that may efficiently provide a platform for implementing a platform, language, database, and cloud agnostic probability of hallucination predicting module configured to implement a model that predicts the probability of hallucination before generation, for any query imposed to an LLM, but the disclosure is not limited thereto.

The client devices 208(1)-208(n) may run interface applications, such as standard web browsers or standalone client applications, which may provide an interface to communicate with the PHPD 202 via the communication network(s) 210 in order to communicate user requests. The client devices 208(1)-208(n) may further include, among other features, a display device, such as a display screen or touchscreen, and/or an input device, such as a keyboard, for example.

Although the exemplary network environment 200 with the PHPD 202, the server devices 204(1)-204(n), the client devices 208(1)-208(n), and the communication network(s) 210 are described and illustrated herein, other types and/or numbers of systems, devices, components, and/or elements in other topologies may be used. It is to be understood that the systems of the examples described herein are for exemplary purposes, as many variations of the specific hardware and software used to implement the examples are possible, as may be appreciated by those skilled in the relevant art(s).

One or more of the devices depicted in the network environment 200, such as the PHPD 202, the server devices 204(1)-204(n), or the client devices 208(1)-208(n), for example, may be configured to operate as virtual instances on the same physical machine. For example, one or more of the PHPD 202, the server devices 204(1)-204(n), or the client devices 208(1)-208(n) may operate on the same physical device rather than as separate devices communicating through communication network(s) 210. Additionally, there may be more or fewer PHPDs 202, server devices 204(1)-204(n), or client devices 208(1)-208(n) than illustrated in FIG. 2. According to exemplary embodiments, the PHPD 202 may be configured to send code at run-time to remote server devices 204(1)-204(n), but the disclosure is not limited thereto.

In addition, two or more computing systems or devices may be substituted for any one of the systems or devices in any example. Accordingly, principles and advantages of distributed processing, such as redundancy and replication also may be implemented, as desired, to increase the robustness and performance of the devices and systems of the examples. The examples may also be implemented on computer system(s) that extend across any suitable network using any suitable interface mechanisms and traffic technologies, including by way of example only teletraffic in any suitable form (e.g., voice and modem), wireless traffic networks, cellular traffic networks, Packet Data Networks (PDNs), the Internet, intranets, and combinations thereof.

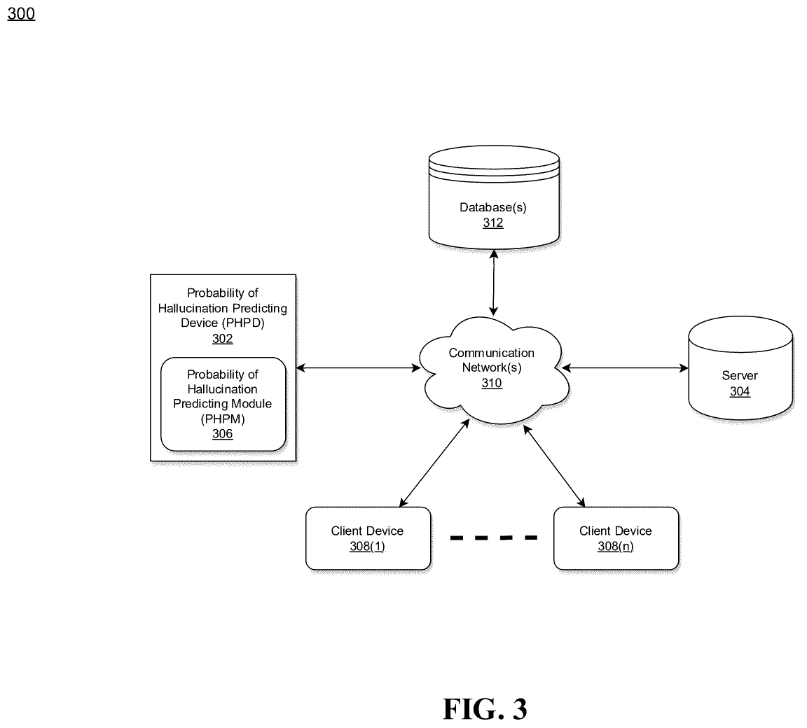

FIG. 3 illustrates a system diagram for implementing a platform, language, and cloud agnostic PHPD having a platform, language, database, and cloud agnostic probability of hallucination predicting module (PHPM) in accordance with an exemplary embodiment.

As illustrated in FIG. 3, the system 300 may include an PHPD 302 within which an PHPM 306 is embedded, a server 304, a database(s) 312, a plurality of client devices 308(1) . . . 308(n), and a communication network 310.

According to exemplary embodiments, the PHPD 302 including the PHPM 306 may be connected to the server 304, and the database(s) 312 via the communication network 310. The PHPD 302 may also be connected to the plurality of client devices 308(1) . . . 308(n) via the communication network 310, but the disclosure is not limited thereto. The database(s) 312 may include rule database.

According to exemplary embodiment, the PHPD 302 is described and shown in FIG. 3 as including the PHPM 306, although it may include other rules, policies, modules, databases, or applications, for example. According to exemplary embodiments, the database(s) 312 may be configured to store ready to use modules written for each API for all environments. Although only one database is illustrated in FIG. 3, the disclosure is not limited thereto. Any number of desired databases may be utilized for use in the disclosed invention herein. The database(s) 312 may be a mainframe database, a log database that may produce programming for searching, monitoring, and analyzing machine-generated data via a web interface, etc., but the disclosure is not limited thereto. In addition, the database(s) 312 may store the large code bases models as directed graphs and graph metrics and graph centrality measures.

According to exemplary embodiments, the PHPM 306 may be configured to receive real-time feed of data from the plurality of client devices 308(1) . . . 308(n) and secondary sources via the communication network 310.

As may be described below, the PHPM 306 may be configured to: implement a generative model; train the generative model via a method of leveraging a simulation algorithm for construction of an encoder for hallucination; receive a query by the generative model from a user via a user interface operatively connected to the generative model; perturb the received query n times into unique variations that retain the original semantic meaning of the received query yet diverge lexically; implement n+1 independent agents to sample an output from each query including the original received query; apply the simulation algorithm on the sampled outputs; derive an empirical estimate into an expected rate of hallucination for the original received query as a ground truth for the encoder; and output a probability of hallucination value for the query received by the generative model before the generative model generates an output in response to the received query, but the disclosure is not limited thereto.

The plurality of client devices 308(1) . . . 308(n) are illustrated as being in communication with the PHPD 302. In this regard, the plurality of client devices 308(1) . . . 308(n) may be “clients” (e.g., customers) of the PHPD 302 and are described herein as such. Nevertheless, it is to be known and understood that the plurality of client devices 308(1) . . . 308(n) need not necessarily be “clients” of the PHPD 302, or any entity described in association therewith herein. Any additional or alternative relationship may exist between either or both of the plurality of client devices 308(1) . . . 308(n) and the PHPD 302, or no relationship may exist.

The first client device 308(1) may be, for example, a smart phone. Of course, the first client device 308(1) may be any additional device described herein. The second client device 308(n) may be, for example, a personal computer (PC). Of course, the second client device 308(n) may also be any additional device described herein. According to exemplary embodiments, the server 304 may be the same or equivalent to the server device 204 as illustrated in FIG. 2.

The process may be executed via the communication network 310, which may comprise plural networks as described above. For example, in an exemplary embodiment, one or more of the plurality of client devices 308(1) . . . 308(n) may communicate with the PHPD 302 via broadband or cellular communication. Of course, these embodiments are merely exemplary and are not limiting or exhaustive.

The computing device 301 may be the same or similar to any one of the client devices 208(1)-208(n) as described with respect to FIG. 2, including any features or combination of features described with respect thereto. The PHPD 302 may be the same or similar to the PHPD 202 as described with respect to FIG. 2, including any features or combination of features described with respect thereto.

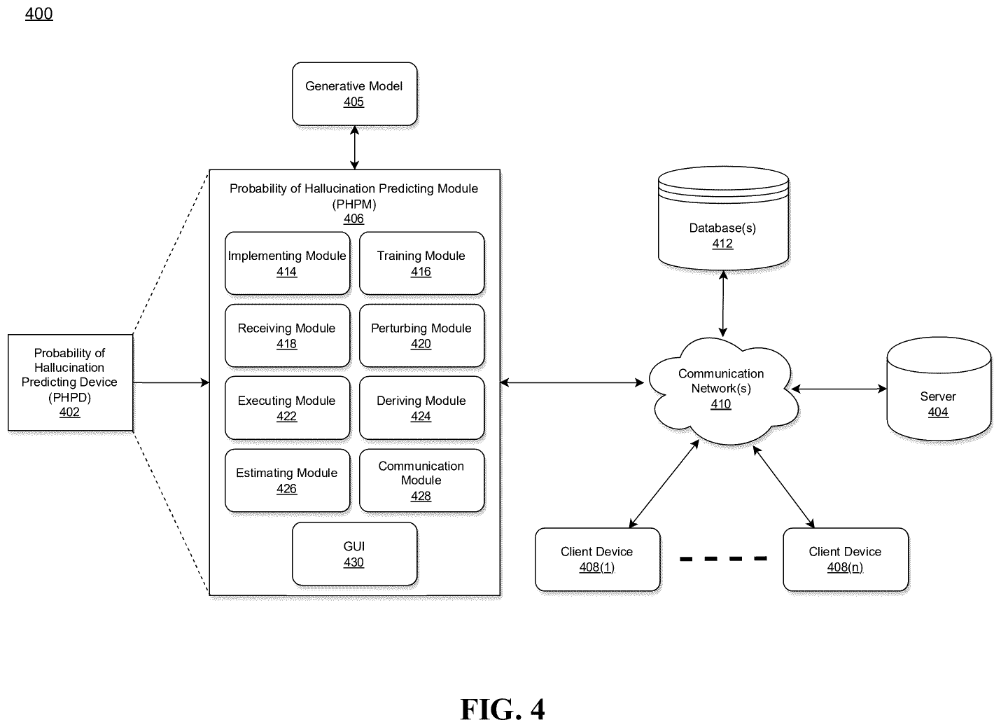

FIG. 4 illustrates a system diagram for implementing a platform, language, database, and cloud agnostic PHPM of FIG. 3 in accordance with an exemplary embodiment.

According to exemplary embodiments, the system 400 may include a platform, language, database, and cloud agnostic PHPD 402 within which a platform, language, database, and cloud agnostic PHPM 406 is embedded, a server 404, database(s) 412, and a communication network 410. According to exemplary embodiments, server 404 may comprise a plurality of servers located centrally or located in different locations, but the disclosure is not limited thereto.

According to exemplary embodiments, the PHPD 402 including the PHPM 406 may be connected to the server 404, a generative model 405, and the database(s) 412 via the communication network 410. The PHPD 402 may also be connected to the plurality of client devices 408(1)-408(n) via the communication network 410, but the disclosure is not limited thereto. The PHPM 406, the server 404, the plurality of client devices 408(1)-408(n), the database(s) 412, the communication network 410 as illustrated in FIG. 4 may be the same or similar to the PHPM 306, the server 304, the plurality of client devices 308(1)-308(n), the database(s) 312, the communication network 310, respectively, as illustrated in FIG. 3.

According to exemplary embodiments, the PHPM 406 may be configured to implement the generative model 405 that predicts the probability of hallucination before generation, for any query imposed to an LLM (not shown), but the disclosure is not limited thereto. Therefore, users can instantly gain insight into hallucination probability and revise a query accordingly.

For example, the generative model 405 implemented by the PHPM 406 may predict both binary and multi-class probabilities of hallucination, enabling a means to judge the query's quality with regards to its propensity to hallucinate. Therefore, the generative model 405 implemented by the PHPM 406 paves the way to revise or cancel a query before generation and the ensuing computational waste. Moreover, the PHPM 406 may provide a lucid means to measure user accountability for hallucinatory queries. The generative model 405 along with the modules of PHPM 406, in combination, may also be referred to as a hallucination bot. This hallucination bot may simply be referred to as a model. In essence, the hallucination bot does not invoke any generation during inference. To derive empirical evidence for the hallucination bot, a Multi-Agent Monte Carlo Simulation may be implemented using a query perturbator (as described below) to craft n variations per query at train time.

Details of the PHPM 406 is provided below with corresponding modules that may be configured to, in combination, results in predicting the probability of hallucination before generation by an LLM, for any query imposed to the LLM, as illustrated in FIGS. 4-6.

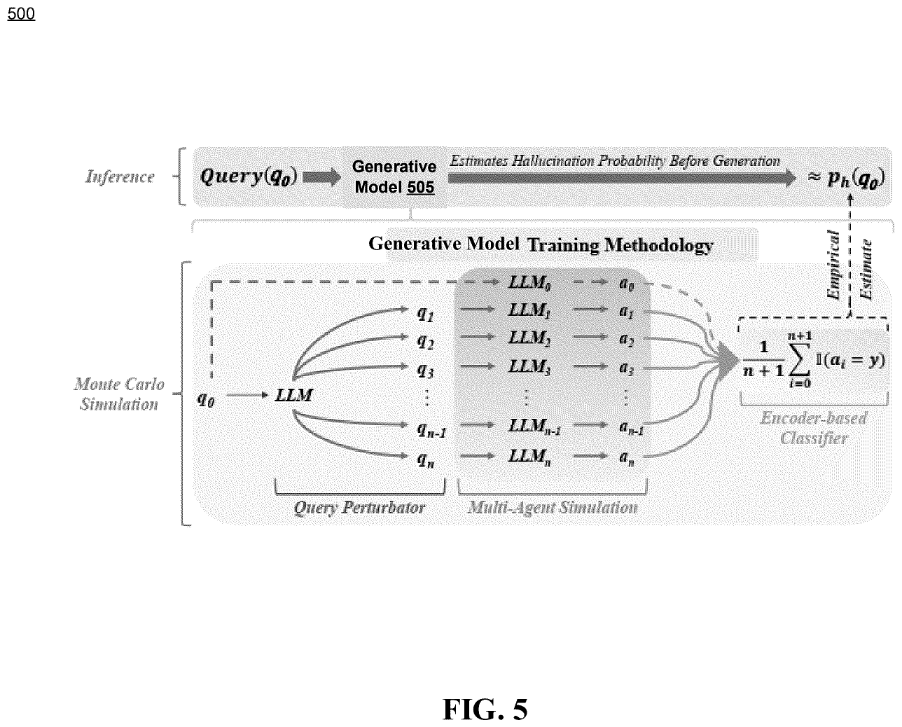

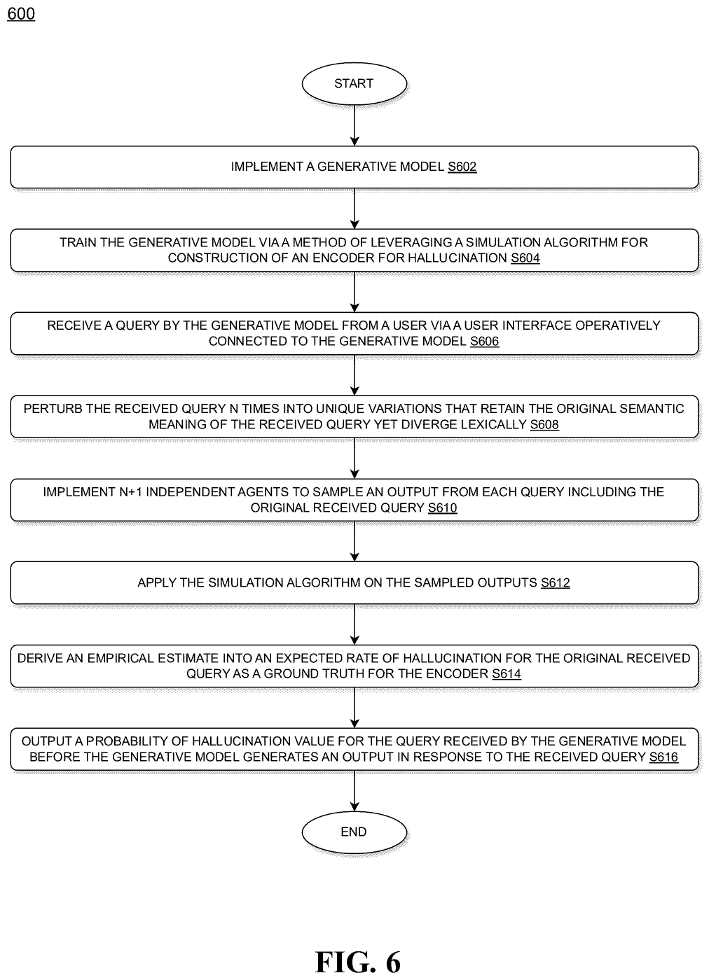

According to exemplary embodiments, as illustrated in FIG. 4, the PHPM 406 may include an implementing module 414, a training module 416, a receiving module 418, a perturbing module 420, an executing module 422, a deriving module 424, an estimating module 426, a communication module 428, and a GUI 430. According to exemplary embodiments, interactions and data exchange among these modules included in the PHPM 406 provide the advantageous effects of the disclosed invention. Functionalities of each module of FIG. 4 may be described in detail below with reference to FIGS. 5-6.

According to exemplary embodiments, each of the implementing module 414, training module 416, receiving module 418, perturbing module 420, executing module 422, deriving module 424, estimating module 426, and the communication module 428 of the PHPM 406 of FIG. 4 may be physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies.

According to exemplary embodiments, each of the implementing module 414, training module 416, receiving module 418, perturbing module 420, executing module 422, deriving module 424, estimating module 426, and the communication module 428 of the PHPM 406 of FIG. 4 may be implemented by microprocessors or similar, and may be programmed using software (e.g., microcode) to perform various functions discussed herein and may optionally be driven by firmware and/or software.

Alternatively, according to exemplary embodiments, each of the implementing module 414, training module 416, receiving module 418, perturbing module 420, executing module 422, deriving module 424, estimating module 426, and the communication module 428 of the PHPM 406 of FIG. 4 may be implemented by dedicated hardware, or as a combination of dedicated hardware to perform some functions and a processor (e.g., one or more programmed microprocessors and associated circuitry) to perform other functions, but the disclosure is not limited thereto. For example, the PHPM 406 of FIG. 4 may also be implemented by Cloud based deployment.

According to exemplary embodiments, each of the implementing module 414, training module 416, receiving module 418, perturbing module 420, executing module 422, deriving module 424, estimating module 426, and the communication module 428 of the PHPM 406 of FIG. 4 may be called via corresponding API, but the disclosure is not limited thereto.

According to exemplary embodiments, the process implemented by the PHPM 406 may be executed via the communication module 428 and the communication network 410, which may comprise plural networks as described above. For example, in an exemplary embodiment, the various components of the PHPM 406 may communicate with the server 404, and the database(s) 412 via the communication module 430 and the communication network 410 and the results (i.e., probability value; empirical estimate, etc.) may be displayed onto the GUI 430. Of course, these embodiments are merely exemplary and are not limiting or exhaustive. The database(s) 412 may include the databases included within the private cloud and/or public cloud and the server 404 may include one or more servers within the private cloud and the public cloud.

According to exemplary embodiments, the implementing module 414 may be configured to implement a generative model 405. The training module 416 may be configured to train the generative model 405 via a method of leveraging a simulation algorithm for construction of an encoder for hallucination. The receiving module 418 may be configured to receive a query by the generative model 405 from a user via a user interface (i.e., GUI 430) operatively connected to the generative model 405. The perturbing module 420 may be configured to perturb the received query n times into unique variations that retain the original semantic meaning of the received query yet diverge lexically. The implementing module 414 may be configured to implement n+1 independent agents to sample an output from each query including the original received query. The executing module 422 may be configured to apply the simulation algorithm on the sampled outputs. The deriving module 424 may be configured to derive an empirical estimate into an expected rate of hallucination for the original received query as a ground truth for the encoder. The GUI 430 may output a probability of hallucination value for the query received by the generative model 405 before the LLM generates an output in response to the received query.

For instance, BERT and ROBERTa encode the full sentence, while GPT-1/2/J only look at prior tokens, and predicting the hallucination rate can be derived in this decoder setting by applying a classification/regression head on the last token. Furthermore, it is possible to train on each partial (intermediate) token to give a cumulative estimate as a user types a query, allowing for incomplete queries to be scored. In addition, an LSTM, RNN, or GRU recurrent neural network (non-transformer) could also be used to generate predictions of hallucinations like an encoder model. Hopefully this would cover most types of models one can employ rather than the encoder-style we actually implemented. According to exemplary embodiments, the PHPM 406 may be further configured to implement the simulation algorithm which may be a Multi-Agent Monte Carlo Simulation algorithm, but the disclosure is not limited thereto. The empirical estimate that is provided through the Multi-Agent Monte Carlo Simulation algorithm implemented by the PHPM 406 may be proportional to an approximation of hallucination rate.

According to exemplary embodiments, the estimating module 426 may be further configured to estimate, by utilizing the trained generative model 405, a binary classification of the received query's propensity to hallucinate (“Yes” or “No”) before generation of any output by the LLM.

According to exemplary embodiments, the estimating module 426 may be further configured to estimate a multi-class hallucination rate estimating an expected value of hallucination via sampling before generation of any output by the LLM.

According to exemplary embodiments, the training module 416 may be further configured to train a binary model to estimate propensity the received query can hallucinate.

According to exemplary embodiments, the training module 416 may be further configured to train a multi-class model to predict expected value of hallucinations when sampled n+1 times.

FIG. 5 illustrates an exemplary model training methodology 500 implemented by the PHPM 406 of FIG. 4 in accordance with an exemplary embodiment. FIG. 5 illustrates an exemplary system overview. For example, a single query q₀, supplied by the user, is perturbed in n different ways. Next, the original and perturbed queries qi are independently answered by the generator agents. This Monte Carlo Simulation provides an estimate into the rate of hallucination pₕ (q₀) for an original query q₀. Undergoing this Multi-Agent Monte Carlo Simulation, covering a plurality of datasets, generative model 505 (i.e., hallucination bot) is trained to predict the probability that any query q₀ will yield a hallucination, and predict the expected value of hallucinations sampled, before generation of an output by the LLM upon which the original query q₀ was imposed.

Comparison between traditional methods of confidence estimation and the hallucination bot implemented by the PHPM 406 as disclosed herein may include that in the former, user inputs a query to generate an output that is accurate or hallucinatory. If hallucinatory, user can end the session or revise the query for iterative rounds of generation. In contrast, the hallucination bot implemented by the PHPM 406 predicts the probability of hallucination for a given query before generation of an output by the LLM upon which the original query q₀ was imposed. Therefore, users can instantly gain insight into hallucination probability and revise a query.

Hallucination itself may not a derivative of any mathematical model and intrinsically, may only be determined by juxtaposing the ground truth with the LLM's generated outputs. Secondly, LLMs frequently advance output quality by different sampling methods such as nucleus sampling. In light of these features, the hallucination bot as disclosed herein is trained via the method of leveraging a Multi-Agent Monte Carlo Simulation for the construction of an encoder for hallucination quantification.

According to exemplary embodiments, the hallucination bot may leverage gpt-3.5-turbo, but not limited thereto, and may be trained via: perturbing over hundreds of thousands queries n times into unique variations that retain the original semantic meaning yet significantly diverge lexically; then, employing n+1 independent agents to sample an output from each query (including the original) at a temperature of 1.0 for diversity; conducting a Monte Carlo Simulation on millions of sampled outputs; deriving an empirical estimate into the expected rate of hallucination pₕ(q₀) for the original query as the ground truth for the encoder.

As a result, the PHPM 406 has culminated in the following pillars of contribution.

The hallucination bot implemented by the PHPM 406, according to exemplary embodiments, is an encoder-based model to derive, before generation, an anticipated rate of hallucination for any type of query.

Moreover, the disclosed method to construct hallucination bot absorbs the computational complexity of Monte Carlo sampling and training prior to the user session. This differs from the prevalent hallucination detection methods that involve sampling during or after the user's current session. Thus, institutions that employ hallucination bot can systematically save on the considerable amount of computational waste engendered by “highly probable” hallucinatory queries.

The hallucination bot, according to exemplary embodiments, also generalizes to systems with Retrieval Augmented Generation (RAG) context or few-shot question answering systems with an LLM generator. Also, it can generalize to systems only accessible via API calls. Thus, in diverse implementation environments, hallucination bot can impart accountability to the user with regards to the query's quality.

In general terms, hallucination refers to a false perception of patterns or objects resulting from one's senses. With regards to LLMs, a myriad of studies have categorized hallucinations into bifurcated structures such as (1) intrinsic hallucination, which refers to the LLM's outputs directly contradicting with the source content for extractive queries, or (2) extrinsic hallucination, which refers to the LLM's outputs being unverifiable by the source content (i.e. irrelevant outputs). From a different angle, (1) factuality hallucinations refer to outputs which directly contradict or fabricate the ground truth while (2) faithfulness hallucinations define outputs that misunderstand the context or intent of the query.

According to exemplary embodiments, the instant disclosure focuses on the aforementioned types of hallucinations and introduce truthful hallucination as a novel concept.

Truthful hallucination is defined as an LLM's inability to answer semantically similar but lexically different perturbations of a query. Understanding truthful hallucination may prove to be essential to account for training bias. Namely, if an LLM has memorized a query and therefore can answer it correctly, but demonstrates the inability to answer similar queries that are worded differently, it might be held accountable. Moreover, truthful hallucination is reflective of user behavior-unless there is a drop-down of query templates, there might almost always be diverse representations of the same query.

According to exemplary embodiments, the hallucination bot as disclosed herein may focus on distilling LLM behavior into a speedy, encoder-based system that can predict hallucination before generation. Foremost, this is in contrast to prior work that uses multiple generations during a user's session to provide self-consistency. Next, the disclosed hallucination bot differs from entropy based, log-prob based, or model based estimation techniques that rely on the LLM's uncertainty to predict hallucinations—these methods focus on the model's bias while the instant disclosure focuses on empirical estimates. Moreover, the instant methodology as disclosed herein with respect to the hallucination bot consists of a Multi-Agent Simulation which stands in stark contrast to the majority of current experiments that have focused on leveraging a single LLM agent to generate outputs from a single query.

According to exemplary embodiments, the training procedure (see, e.g., FIG. 5) for hallucination bot (i.e., generative model 505) may include, but not limited to, the following: perturbing hundreds of thousands of queries n times; employing n+1 independent LLM agents; sampling an output from each query; conducting a Monte Carlo Simulation on the millions of sampled outputs; and training an encoder-based classifier.

Perturbations help comprehend truthful hallucination. The PHPM 406 induce diversity to disentangle the generation process from any potential training bias and emulate real-life scenarios, in which users unintentionally create variations of the same query.

Thus, the query perturbator may be a gpt-3.5-turbo LLM agent T that generates n=5 perturbations to the original query q₀ while retaining the same semantic meaning. Note that in practice, there are n+1=6 transformations because for a given query q₀, the system defines T₀(q₀)=I(q₀)=q₀ as an identity transform. Therefore, the original query may always be included in the set of transformed queries for the next step. In effect, the generation process can be summarized as returning a set of Q={q₀, q₁, . . . , qₙ} query perturbations of size n+1. The query perturbator's singular purpose is to: Rewrite the query in {n} radically different ways. One prompt call is sufficient to discourage duplicates. Temperature is set to 1.0 to prioritize creativity and lexical diversity.

$$Q = T ( {q}_{0} ) = [ \begin{matrix}I ( {q}_{0} ) \\ {T}_{1} ( {q}_{0} ) \\ ⋮ \\ {T}_{n} ( {q}_{0} )\end{matrix} ] = [ \begin{matrix}{q}_{0} \\ {q}_{1} \\ ⋮ \\ {q}_{n}\end{matrix} ]$$

According to exemplary embodiments, the same set of parameters are used for both the query perturbator and output generator.

Next, the output generator is deployed for each perturbation due to the following reasons. Given the complexity of LLMs with nucleus sampling decoding, analyzing a single output from a single query may not be comprehensive enough to determine hallucination. Furthermore, given the risk of over-training LLMs, their opaque training data, and propensity to memorize, generating multiple outputs from the same query does not eliminate training bias.

According to exemplary embodiments, a new generation process should be launched each time to answer the next perturbed query to ensure a truly independent output generation process. Thus, for the perturbed set Q for a sample q₀, the output generator consists of |Q|=n+1 independent LLM agents to generate outputs aᵢ∈A for each variation qᵢ∈Q. The LLM agent may receive (1) for extractive queries, a prompt with the query q₁, alongside context cᵢ, (2) for multiple-choice queries, candidate choices kᵢ∈K, and (3) for abstractive queries, no additional context. Temperature for all experiments is set to 1.0 to stress-test and encourage diversity. LLM temperature is a parameter that influences the language model's output, determining whether the output is more random and creative or more predictable. A temperature value of 1.0 corresponds to the standard softmax function, where the probabilities of the predicted words are not scaled. The softmax function is defined by a lone hyperparameter, the temperature, that is commonly set to one or regarded as a way to tune model confidence after training.

As disclosed earlier, hallucination may be the outcome of multiple confounding variables—thus, it is highly unlikely that a tractable closed-form solution may be able to model hallucinations. Thus, the PHPM 406 implements a Monte Carlo Simulation as a means to derive empirical estimations of hallucination rates in LLMs, since this method is frequently leveraged to map probability in the presence of random variable inference. Thus, the PHPM 406 estimates the probability density that a query induces hallucination.

Once the Monte Carlo Simulation is complete for training corpus composed of hundreds of thousands of queries spanning a plurality of different datasets, the PHPM 406 starts training the classifier. These queries may encompass extractive, multiple-choice, and abstractive scenarios. Each scenario, with or without additional context, may affect the hallucination rate of gpt-3.5-turbo. The estimates provided through the Monte Carlo Simulation as implemented by the PHPM 406 are proportional to an approximation of hallucination rates.

With a synthetic labeled set of queries q₀ and their rate of hallucinations pₕ (q₀), the PHPM 406 trains an encoder-style classifier based on Bidirectional Encoder Representations from Transformers (BERT) and ROBERTa to estimate the hallucination probability density from our Monte Carlo Simulation. BERT is a language model based on the transformer architecture, notable for its dramatic improvement over previous state of the art models. ROBERTa uses a more aggressive Byte-Pair Encoding (BPE) algorithm compared to BERT, leading to a larger number of sub-word units and a more fine-grained representation of the language.

According to exemplary embodiments, the term “encoder” as disclosed herein is not limited to an encoder only. The term “encoder” may broadly encompass one or more of the following: encoder, auto-encoding encoder, decoder, autoregressive decoder, sequence model, e.g., Long Short-Term Memory (LSTM) network or Recurrent Neural Network (RNN) or Gated Recurrent Unit (GRU), but the disclosure is not limited thereto.

For example, BERT and ROBERTa encode the full sentence, while GPT-1/2/J only look at prior tokens, and predicting the hallucination rate can be derived in this decoder setting by applying a classification or regression head on the last token. Furthermore, it may be possible to train on each partial (intermediate) token to give a cumulative estimate as a user types a query, allowing for incomplete queries to be scored. In addition, an LSTM, RNN, or GRU recurrent neural network (non-transformer) could also be used to generate predictions of hallucinations like an encoder model.

According to exemplary embodiments, the PHPM 406 may train two versions: a binary model to estimate the propensity a query can hallucinate, and a multi-class model to predict the expected value of hallucinations if sampled n+1 times.

According to exemplary embodiments, experiments implemented by the PHPM 406 constrain the number of perturbations to n=5, and when including the original query and output, the PHPM 406 can model the hallucination rate for n+1=6 modes.

According to exemplary embodiments, the PHPM 406 implements an ablation study to explore if incorporating the query's scenario mitigates hallucinations. To create the prompt, the PHPM 406 computes the original query q₀ with either extractive, multiple-choice, or abstractive scenarios, using the format «{tag} {q₀}». The additional context provides valuable signals related to the hallucination rate of the original query. Furthermore, this technique is applied to distinguish the experimental results from reused datasets in different scenarios. The queries are encoded exactly as they appear in the original datasets.

According to exemplary embodiments, the probability of truthful hallucinations for a query q₀, denoted as pₕ(q₀), can be empirically estimated based on the output a₌ᵢ∈A of the Multi-Agent Monte Carlo Simulation. The indicator function I is defined to measure the correctness of an output aᵢ with respect to the ground truth y for query q₀.

$${p}_{h} ( {q}_{0} ) \approx \frac{1}{n + 1} {\sum }_{i = 0}^{n + 1} 𝕀 [ {a}_{i} = y ]$$

According to exemplary embodiments, to assess the propensity to hallucinate, the PHPM 406 simplifies the problem by considering two response values: whether q₀ produces any hallucination or not. Thus, the PHPM 406 defines the binary values for the probability of any hallucination as pₕ(q₀).

$${p}_{h} ( {q}_{0} ) = \{ \begin{matrix}1 & if {p}_{h} ( {q}_{0} ) > 0 \\ 0 & if {p}_{h} ( {q}_{0} ) = 0\end{matrix}$$

According to exemplary embodiments, the hallucination bot may be trained to estimate the occurrence of hallucinations when queried and sampled under n+1 trials. To facilitate training, the PHPM 406 converts the proportion into discrete classes by multiplying the original estimate pₕ(q₀) by the number of agents n+1. This transformed variable is denoted as [symbol] [pₕ(q₀)].

$$𝔼 [ {p}_{h} ( {q}_{0} ) ] = ⌊ ( n + 1 ) \cdot {p}_{h} ( {q}_{0} ) ⌋$$

According to exemplary embodiments, two key metrics are observed: accuracy and agreement. The concept of truthful hallucination focuses on the accuracy of individual agents. In addition, the PHPM 406 analyzes the level of agreement as an indicator of correlation. Moreover, the simulation's reliability is assessed at the corpus level.

According to exemplary embodiments, accuracy serves as the measure of correctness in the evaluation by comparing the generated output aᵢ to the ground truth string y, aiming for an almost exact match. For multiple-choice queries, the PHPM 406 considers the choice label. However, due to minor variations in special characters, a partial, case-insensitive matching approach can be adopted using the Fuzzy string matching library. If there is a match between the output aᵢ and the ground truth y, the PHPM 406 assigns [symbol] [aᵢ=y] [symbol] 1; otherwise, 0. To assess the range of correctness for each experiment, the PHPM 406 compares the results of the original query q₀ and its output a₀ juxtaposed to the mode (most common) vote. In addition, the lower bound (all correct) and upper bound (at least one correct) accuracy are presented across n+1=6 agents.

Accuracy alone is insufficient for evaluating the agreement among multiple agents when analyzing truthful hallucinations. To address this limitation, the PHPM 406 utilizes several statistical measures: Item Difficulty (μ_{D}), Fleiss's Generalized κ, Mean Certainty (Hₙ), and Gibbs' M₂ Index. These measures enable the assessment with regards to the level of agreement among independent samplings of a query, regardless of correctness. For example, if all LLM agents provide the same incorrect answer, high agreement indicates a misconception.

According to exemplary embodiments, the PHPM 406 implements Cronbach's a to assess the internal consistency of the Monte Carlo Simulation, as a corpus-level statistic.

According to exemplary embodiments, the Monte Carlo Simulation utilizes two LLM components: the query perturbator and output generator as disclosed above.

According to exemplary embodiments, the PHPM 406 implements HuggingFace's Trainer class with the Adam optimizer algorithm for training, reporting efficiency and training times. Adam is an optimization algorithm that can be used instead of the classical stochastic gradient descent procedure to update network weights iterative based in training data. All experiments are conducted on an AWS EC2 instance with a single GPU. To address label imbalance, the PHPM 406 implements a weighted loss where each class weight is assigned to its inverted frequency in the training set. For the multi-class predictor, the PHPM 406 trains a cross-entropy and ordinal model. The train, validation, and test splits follow the original divisions of the datasets.

FIG. 6 illustrates an exemplary flow chart of a process 600 implemented by the platform, language, database, and cloud agnostic PHPM 406 of FIG. 4 for implementing a model that predicts the probability of hallucination before generation, for any query imposed to an LLM in accordance with an exemplary embodiment. It may be appreciated that the illustrated process 600 and associated steps may be performed in a different order, with illustrated steps omitted, with additional steps added, or with a combination of reordered, combined, omitted, or additional steps.

As illustrated in FIG. 6, at step S602, the process 600 may include implementing a generative model.

At step S604, the process 600 may include training the generative model via a method of leveraging a simulation algorithm for construction of an encoder for hallucination.

At step S606, the process 600 may include receiving a query by the generative model from a user via a user interface operatively connected to the generative model.

At step S608, the process 600 may include perturbing the received query n times into unique variations that retain the original semantic meaning of the received query yet diverge lexically.

At step S610, the process 600 may include implementing n+1 independent agents to sample an output from each query including the original received query.

At step S612, the process 600 may include applying the simulation algorithm on the sampled outputs.

At step S614, the process 600 may include deriving an empirical estimate into an expected rate of hallucination for the original received query as a ground truth for the encoder.

At step S616, the process 600 may include outputting a probability of hallucination value for the query received by the generative model before the LLM generates an output in response to the received query imposed to the LLM.

According to exemplary embodiments, in implementing the process 600, the simulation algorithm may be a Multi-Agent Monte Carlo Simulation algorithm, but the disclosure is not limited there, and the empirical estimate that is provided through the Multi-Agent Monte Carlo Simulation algorithm may be proportional to an approximation of hallucination rate.

According to exemplary embodiments, the process 600 may further include: estimating, by the trained generative model, a binary classification of the received query's propensity to hallucinate before generation.

According to exemplary embodiments, the process 600 may further include: estimating a multi-class hallucination rate estimating an expected value of hallucination via sampling before generation.

According to exemplary embodiments, the process 600 may further include: training a binary model to estimate propensity the received query can hallucinate.

According to exemplary embodiments, the process 600 may further include: training a multi-class model to predict expected value of hallucinations when sampled n+1 times.

According to exemplary embodiments, the PHPD 402 may include a memory (e.g., a memory 106 as illustrated in FIG. 1) which may be a non-transitory computer readable medium that may be configured to store instructions for implementing a platform, language, database, and cloud agnostic PHPM 406 for predicting probability of hallucination before generation for a query imposed to an LLM as disclosed herein. The PHPD 402 may also include a medium reader (e.g., a medium reader 112 as illustrated in FIG. 1) which may be configured to read any one or more sets of instructions, e.g., software, from any of the memories described herein. The instructions, when executed by a processor embedded within the PHPM 406 or within the PHPD 402, may be used to perform one or more of the methods and processes as described herein. In a particular embodiment, the instructions may reside completely, or at least partially, within the memory 106, the medium reader 112, and/or the processor 104 (see FIG. 1) during execution by the PHPD 402.

According to exemplary embodiments, the instructions, when executed, may cause a processor embedded within the PHPM 406 or the PHPD 402 to perform the following: implementing a generative model; training the generative model via a method of leveraging a simulation algorithm for construction of an encoder for hallucination; receiving a query by the generative model from a user via a user interface operatively connected to the generative model; perturbing the received query n times into unique variations that retain the original semantic meaning of the received query yet diverge lexically; implementing n+1 independent agents to sample an output from each query including the original received query; applying the simulation algorithm on the sampled outputs; deriving an empirical estimate into an expected rate of hallucination for the original received query as a ground truth for the encoder; and outputting a probability of hallucination value for the query received by the generative model before the generative model generates an output in response to the received query. According to exemplary embodiments, the processor may be the same or similar to the processor 104 as illustrated in FIG. 1 or the processor embedded within the PHPD 202, PHPD 302, PHPD 402, and PHPM 406 which is the same or similar to the processor 104.

According to exemplary embodiments, in implementing the process by the processor 104, the simulation algorithm may be a Multi-Agent Monte Carlo Simulation algorithm, but the disclosure is not limited there, and the empirical estimate that is provided through the Multi-Agent Monte Carlo Simulation algorithm may be proportional to an approximation of hallucination rate.

According to exemplary embodiments, the instructions, when executed, may cause the processor 104 to further perform the following: estimating, by the trained generative model, a binary classification of the received query's propensity to hallucinate before generation.

According to exemplary embodiments, the instructions, when executed, may cause the processor 104 to further perform the following: estimating a multi-class hallucination rate estimating an expected value of hallucination via sampling before generation.

According to exemplary embodiments, the instructions, when executed, may cause the processor 104 to further perform the following: training a binary model to estimate propensity the received query can hallucinate.

According to exemplary embodiments, the instructions, when executed, may cause the processor 104 to further perform the following: training a multi-class model to predict expected value of hallucinations when sampled n+1 times.

According to exemplary embodiments as disclosed above in FIGS. 1-6, technical improvements effected by the instant disclosure may include a platform for implementing a platform, language, database, and cloud agnostic probability of hallucination predicting module configured to implement a model that predicts the probability of hallucination before generation, for any query imposed to an LLM, but the disclosure is not limited thereto. Therefore, users can instantly gain insight into hallucination probability and revise a query accordingly. For example, the model implemented by the probability of hallucination predicting module may predict both binary and multi-class probabilities of hallucination, enabling a means to judge the query's quality with regards to its propensity to hallucinate. Therefore, the model paves the way to revise or cancel a query before generation and the ensuing computational waste. Moreover, it may provide a lucid means to measure user accountability for hallucinatory queries.

Although the invention has been described with reference to several exemplary embodiments, it is understood that the words that have been used are words of description and illustration, rather than words of limitation. Changes may be made within the purview of the appended claims, as presently stated and as amended, without departing from the scope and spirit of the present disclosure in its aspects. Although the invention has been described with reference to particular means, materials and embodiments, the invention is not intended to be limited to the particulars disclosed; rather the invention extends to all functionally equivalent structures, methods, and uses such as are within the scope of the appended claims.

For example, while the computer-readable medium may be described as a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the embodiments disclosed herein.

The computer-readable medium may comprise a non-transitory computer-readable medium or media and/or comprise a transitory computer-readable medium or media. In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals such as a signal communicated over a transmission medium. Accordingly, the disclosure is considered to include any computer-readable medium or other equivalents and successor media, in which data or instructions may be stored.

Although the present application describes specific embodiments which may be implemented as computer programs or code segments in computer-readable media, it is to be understood that dedicated hardware implementations, such as application specific integrated circuits, programmable logic arrays and other hardware devices, can be constructed to implement one or more of the embodiments described herein. Applications that may include the various embodiments set forth herein may broadly include a variety of electronic and computer systems. Accordingly, the present application may encompass software, firmware, and hardware implementations, or combinations thereof. Nothing in the present application should be interpreted as being implemented or implementable solely with software and not hardware.

Although the present specification describes components and functions that may be implemented in particular embodiments with reference to particular standards and protocols, the disclosure is not limited to such standards and protocols. Such standards are periodically superseded by faster or more efficient equivalents having essentially the same functions. Accordingly, replacement standards and protocols having the same or similar functions are considered equivalents thereof.

The illustrations of the embodiments described herein are intended to provide a general understanding of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, may be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for predicting probability of hallucination before generation for a query imposed to a Large Language Model (LLM) by utilizing one or more processors along with allocated memory, the method comprising:
implementing a generative model;
training the generative model via a method of leveraging a simulation algorithm for construction of an encoder for hallucination;
receiving a query by the generative model from a user via a user interface operatively connected to the generative model;
perturbing the received query n times into unique variations that retain the original semantic meaning of the received query yet diverge lexically;
implementing n+1 independent agents to sample an output from each query including the original received query;
applying the simulation algorithm on the sampled outputs;
deriving an empirical estimate into an expected rate of hallucination for the original received query as a ground truth for the encoder; and
outputting a probability of hallucination value for the query received by the generative model before the LLM generates an output in response to the received query.

2. The method according to claim 1, wherein the simulation algorithm is a Multi-Agent Monte Carlo Simulation algorithm.

3. The method according to claim 2, wherein the empirical estimate that is provided through the Multi-Agent Monte Carlo Simulation algorithm is proportional to an approximation of hallucination rate.

4. The method according to claim 1, further comprising:
estimating, by the trained generative model, a binary classification of the received query's propensity to hallucinate before generation.

5. The method according to claim 1, further comprising:
estimating a multi-class hallucination rate estimating an expected value of hallucination via sampling before generation.

6. The method according to claim 1, further comprising:
training a binary model to estimate propensity the received query can hallucinate.

7. The method according to claim 1, further comprising:
training a multi-class model to predict expected value of hallucinations when sampled n+1 times.

8. A system for predicting probability of hallucination before generation for a query imposed to a Large Language Model (LLM), the system comprising:
a processor; and
a memory operatively connected to the processor via a communication interface, the memory storing computer readable instructions, when executed, causes the processor to:
implement a generative model;
train the generative model via a method of leveraging a simulation algorithm for construction of an encoder for hallucination;
receive a query by the generative model from a user via a user interface operatively connected to the generative model;
perturb the received query n times into unique variations that retain the original semantic meaning of the received query yet diverge lexically;
implement n+1 independent agents to sample an output from each query including the original received query;
apply the simulation algorithm on the sampled outputs;
derive an empirical estimate into an expected rate of hallucination for the original received query as a ground truth for the encoder; and
output a probability of hallucination value for the query received by the generative model before the LLM generates an output in response to the received query.

9. The system according to claim 8, wherein the wherein the simulation algorithm is a Multi-Agent Monte Carlo Simulation algorithm.

10. The system according to claim 9, wherein the empirical estimate that is provided through the Multi-Agent Monte Carlo Simulation algorithm is proportional to an approximation of hallucination rate.

11. The system according to claim 8, wherein the processor is further configured to:
estimate, by the trained generative model, a binary classification of the received query's propensity to hallucinate before generation.

12. The system according to claim 8, wherein the processor is further configured to:
estimate a multi-class hallucination rate estimating an expected value of hallucination via sampling before generation.

13. The system according to claim 8, wherein the processor is further configured to train a binary model to estimate propensity the received query can hallucinate.

14. The system according to claim 8, wherein the processor is further configured to:
train a multi-class model to predict expected value of hallucinations when sampled n+1 times.

15. A non-transitory computer readable medium configured to store instructions for predicting probability of hallucination before generation for a query imposed to a Large Language Model (LLM), the instructions, when executed, cause a processor to perform the following:
implementing a generative model;
training the generative model via a method of leveraging a simulation algorithm for construction of an encoder for hallucination;
receiving a query by the generative model from a user via a user interface operatively connected to the generative model;
perturbing the received query n times into unique variations that retain the original semantic meaning of the received query yet diverge lexically;
implementing n+1 independent agents to sample an output from each query including the original received query;
applying the simulation algorithm on the sampled outputs;
deriving an empirical estimate into an expected rate of hallucination for the original received query as a ground truth for the encoder; and
outputting a probability of hallucination value for the query received by the generative model before the LLM generates an output in response to the received query.

16. The non-transitory computer readable medium according to claim 15, wherein the simulation algorithm is a Multi-Agent Monte Carlo Simulation algorithm, and wherein the empirical estimate that is provided through the Multi-Agent Monte Carlo Simulation algorithm is proportional to an approximation of hallucination rate.

17. The non-transitory computer readable medium according to claim 15, wherein the instructions, when executed, cause the processor to further perform the following:
estimating, by the trained generative model, a binary classification of the received query's propensity to hallucinate before generation.

18. The non-transitory computer readable medium according to claim 15, wherein the instructions, when executed, cause the processor to further perform the following:
estimating a multi-class hallucination rate estimating an expected value of hallucination via sampling before generation.

19. The non-transitory computer readable medium according to claim 15, wherein the instructions, when executed, cause the processor to further perform the following: training a binary model to estimate propensity the received query can hallucinate.

20. The non-transitory computer readable medium according to claim 15, wherein the instructions, when executed, cause the processor to further perform the following:
training a binary model to estimate propensity the received query can hallucinate.
